(19) United States
(12) Patent Application Publication
(10) Pub. No.: US 2007/0026564 A1
(43) Pub. Date: Feb. 1, 2007

(54) METHOD FOR FORMING MICROLENSES OF DIFFERENT CURVATURES AND FABRICATING PROCESS OF SOLID-STATE IMAGE SENSOR

(76) Inventors: Hsin-Ping Wu, Yilan County (TW); Chia-Huei Lin, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,776

(22) Filed: Jul. 8, 2005

(51) Int. Cl. H01L 21/00

(52) U.S. Cl. 438/69; 438/70

(57) ABSTRACT

A method for forming microlenses of different curvatures is described, wherein a transparent photosensitive layer is formed on a substrate having a planar upper surface. A photomask is used to pattern the photosensitive layer, wherein the photomask has at least two patterns of different transparencies thereon such that at least two islands of different thicknesses are defined from the photosensitive layer. Then, the at least two islands are heated and softened to form at least two microlenses of different curvatures.

### BACKGROUND OF THE INVENTION

1. Field of the Invention

The present invention relates to a method for fabricating optical components. More particularly, the present invention relates to a method for forming microlenses of different curvatures, and to a fabricating process of a solid-state image sensor which utilizes the method so that the sensitivities to different color lights can be optimized respectively.

2. Description of the Related Art

A solid-state image sensor, such as a CCD image sensor or CMOS image sensor (CIS) is essentially composed of red, green and blue pixel sensors that are respectively equipped with red, green and blue filters. To increase the quantum yield of incident light for improving the sensitivity, a microlens can be formed over each color filter to focus the incident light, as described in U.S. Pat. No. 6,379,992, for example.

Referring to FIG. 1A, in a typical microlens process of a CIS device, a substrate 100 is provided, on which a passivation layer 110 for protecting the circuit of the sensor, blue, green and red filters 120, 130 and 140, and a planarization layer 150 have been formed. A transparent photosensitive layer 160 is formed on the planarization layer 150, and then a photomask 170 having opaque patterns (transparency=0%) thereon is used to pattern the photosensitive layer 160 into islands 160a of the same thickness, wherein each island 160a is located over one color filter.

Referring to FIG. 1B, the islands 160a are heated and softened such that the surface tension makes their surfaces spherical, thus forming multiple microlenses 160b, which have the same curvature because all of the islands 160a have the same thickness. Hence, the focal lengths of the three microlenses 160b formed over the blue, green and red filters 120, 130 and 140 are the same.

However, as shown in FIG. 1B, because respective maximal absorption regions 122, 132 and 142 of blue, green and red lights 124, 134 and 144 are different in depth in the substrate 100, the absorptions of the blue, green and red lights cannot be optimized respectively with the microlenses 160b of the same curvature that have a single focal length only. Hence, the sensitivities of the image sensor to different color lights are different to cause chromatic deviation of the recorded images.

To solve the above problem, for example, the method disclosed in U.S. Pat. No. 5,592,223 can be used, in which the sensitivities to different color lights are equalized by varying respective areas and/or curvatures of the microlenses formed over different color filters. Besides, the method provided in U.S. Pat. No. 6,643,386 equalizes the sensitivities to different color lights by altering respective colors or shapes of the microlenses over different color filters, wherein the shapes include areas and curvatures.

However, when the sensitivities are equalized by forming microlenses of different areas or colors, a color light of higher sensitivity is made to have a lowered intensity incident to the corresponding sensor diode. Therefore, the overall sensitivity of the CIS device cannot be improved. In addition, forming microlenses of different colors needs more then one lithography processes, so that the fabrication is tedious.

On the other hand, when the sensitivities are equalized by forming microlenses of different curvatures, the sensitivities to different color lights can be respectively optimized by adjusting respective curvatures to get different focal lengths. However, this microlens process is very tedious because three lithography processes are conducted to form photoresist islands of three thicknesses for making the three curvatures.

### SUMMARY OF THE INVENTION

In view of the foregoing, one object of this invention is to provide a method for forming microlenses of different curvatures, by which the sensitivities of a solid-state image sensor to different color lights can be optimized respectively.

Another object of this invention is to provide a fabricating process of a solid-state image sensor, which utilizes the above method of this invention to respectively optimize the sensitivities to different color lights.

The method for forming microlenses of different curvatures of this invention is described as follows. A transparent photosensitive layer is formed on a substrate that has a planar upper surface, and then a photomask is used to pattern the photosensitive layer. The photomask has at least two patterns of different transparencies thereon, such that at least two islands of different thicknesses are defined from the photosensitive layer, wherein the higher the transparency of a pattern is, the thinner the corresponding island is. Then, the at least two islands are heated and softened to form at least two microlenses of different curvatures, wherein the thicker an island is, the larger the curvature of the corresponding microlens is.

In an embodiment of this invention, the above method is applied to a fabricating process of a solid-state image sensor, such as a CMOS image sensor. In the solid-state image sensor, the sensors of first to third color lights respectively have a first, a second and a third maximal absorption regions that are different in depth in the substrate. The photomask used has three patterns of three different transparencies thereon, such that three islands of three different thicknesses are defined to form three microlenses of three different curvatures. The three islands are formed over the first, the second and the third maximal absorption regions, respectively, in a manner that the deeper a maximal absorption region is, the thinner the corresponding island is, such that the microlenses are formed with three different curvatures capable of focusing the first to third color lights respectively to the first, the second and the third maximal absorption regions.

Accordingly, in the method for fabricating a solid-state image sensor of this invention, the above method for forming three microlenses of three curvatures is applied after the color filters of the three color lights are formed. The planar upper surface of the substrate may be the upper surface of a planarization layer that is formed covering the color filters. The three islands of three thicknesses are respectively formed over the first, the second and the third color filters in the same manner as mentioned above, such that the three microlenses are formed with three different curvatures capable of focusing the first to third color lights respectively to the first, the second and the third maximal absorption regions.

Since the microlenses of different curvatures are form with only one lithography process via the variation of pattern transparencies on a single photomask, much process time is saved as compared with the prior art that forms microlenses of different colors or curvatures with more than one lithography processes. Meanwhile, because the first to third color lights are respectively focused to the first, the second and the third maximal absorption regions, the sensitivities of the image sensor to different color lights are optimized respectively. Hence, the overall sensitivity of the image sensor is improved as compared with the prior art that forms microlenses of different areas or colors.

It is to be understood that both the foregoing general description and the following detailed description are exemplary, and are intended to provide further explanation of the invention as claimed.

### BRIEF DESCRIPTION OF THE DRAWINGS

FIGS. 1A-1B illustrate a process flow of fabricating a CMOS image sensor in the prior art in a cross-sectional view, including a process of forming microlenses.

FIGS. 2A-2B illustrate a process flow of fabricating a CMOS image sensor (CIS) according to a preferred embodiment of this invention in a cross-sectional view, which includes a process of forming microlenses of different curvatures.

FIG. 3 illustrates an example of the thickness variation of the island (microlens material 260x) defined from the photosensitive layer with respect to the transparency change of the mask pattern in the preferred embodiment of this invention.

### DESCRIPTION OF THE PREFERRED EMBODIMENTS

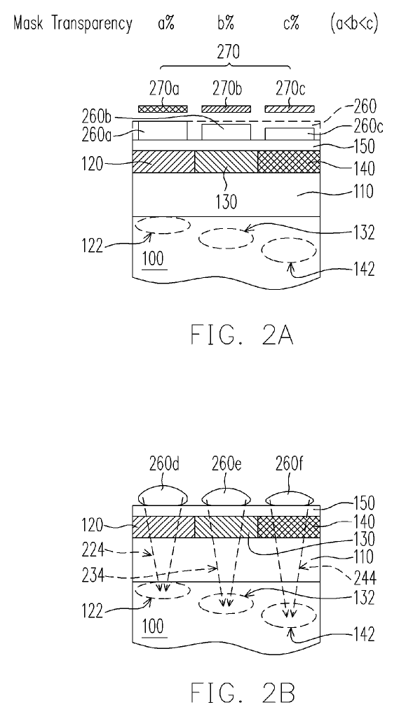

This invention will be further explained with a fabricating process of a CMOS image sensor as a preferred embodiment, which is illustrated in FIGS. 2A-2B in a cross-sectional view. In this embodiment, the first to third color lights as mentioned above are red light, green light and blue light, respectively, but are not limited to those. The three color lights may alternatively be magenta, cyan and yellow lights, or any other combination of three color lights that can be combined to obtain full colors.

Referring to FIG. 2A, a semiconductor substrate 100 is provided, having been formed with a circuit (not shown) thereon, which essentially includes CMOS transistors, sensor diodes and necessary interconnect structures, etc. Respective depths D1, D2 and D3 of the maximal absorption regions 142, 132 and 122 of red, green and blue lights in the substrate 100 satisfy the inequality of “D1>D2>D3”.

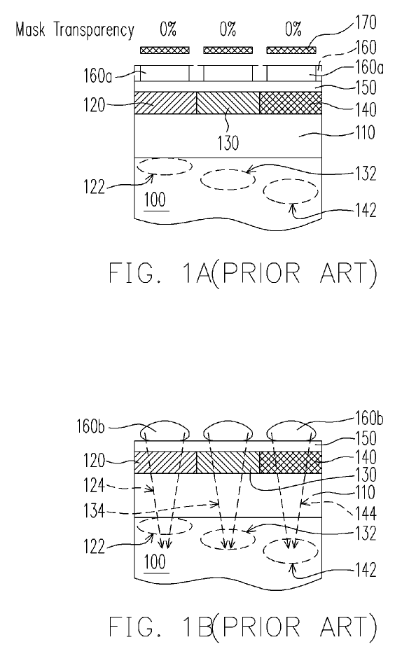

Then, a passivation layer 110, such as a thick SiO2 layer, is formed over the substrate 100 covering the circuit to protect the circuit. It is noted that one skilled in the art can easily find a circuit of CMOS image sensor in many references and the circuit is no feature of this invention, so the circuit is not depicted in the figures. Meanwhile, the photosensing areas of the three color lights are depicted contiguously for simplification, as in FIGS. 1A and 1B.

After that, a blue filter 120, a green filter 130 and a red filter 140 are respectively formed on the passivation layer 110. The blue, green or red filter 120, 130 or 140 is usually defined from one colored photosensitive layer, such as one colored photoresist layer, so that three lithography processes are required to complete the filter fabrication.

Thereafter, microlenses may be formed directly on the color filters 120-140 if the top heights of the color filters 120-140 are made substantially the same, i.e., the thicknesses of the color filters 120-140 are made substantially the same. However, considering that the thicknesses of the color filters 120-140 formed with different lithography processes are possibly non-uniform, it is preferred to form the microlenses after a planarization layer 150 is formed covering the color filters 120, 130 and 140. The planarization layer 150 may include an organic spin-on material, such as a spin-on polymer (SOP).

Referring to FIG. 2A again, a transparent photosensitive layer 260 is formed over the color filters 120-140. A lithography process using a photomask 270, which has three patterns 270a, 270b and 270c of different transparencies, is performed to pattern the transparent photosensitive layer 260 into islands 260a, 260b and 260c of three different thicknesses that are respectively over the color filters 120, 130 and 140 and are microlens materials that will be converted to microlenses later. The transparent photosensitive layer 260 is transparent to visible light but not to the UV light used in the lithography process, and may include a positive photoresist material.

The photomask 270 has a first pattern 270a with a transparency of a %, a second pattern 270b with a transparency of b % and a third pattern with a transparency c % for defining the microlenses over the blue filter 120, the green filter 130 and the red filter 140, respectively, wherein a, b and c satisfy the inequality of “c>b>a”. As known in the art, when the transparency of a mask pattern is 0, the corresponding portion of the photosensitive layer is not solublized at all in the lithography process, so that the island formed therefrom can have a maximal thickness.

However, when the transparency of a mask pattern is larger than 0 but under a certain value, a surface layer of the corresponding portion of the photosensitive layer subjecting to sufficient irradiation is solublized, so that the island formed therefrom has a reduced thickness. Accordingly, the higher the transparency of a mask pattern is, the thinner the corresponding island defined thereby is. Therefore, the island 260b over the green filter 130 is thinner than the island 260a over the blue filter 120, and the island 260c over the red filter 140 is thinner than the island 260b over the green filter 130.

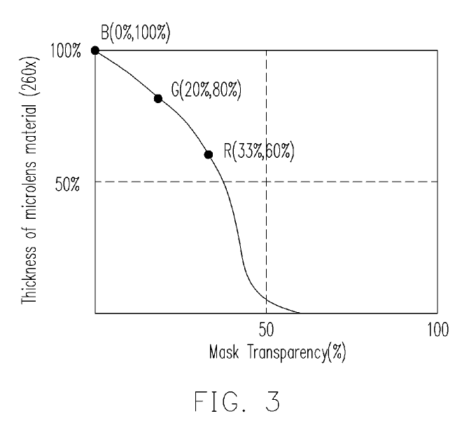

For example, as shown in FIG. 3, the values of a, b and c may be 0, 20 and 33, respectively, such that the thicknesses of the islands 260a, 260b and 260c respectively formed over the blue (B) filter 120, the green (G) filter 130 and the red (R) filter 140 are 100%, 80% and 60%, respectively, with the thickness of the undefined photosensitive layer 260 set as 100%.

Referring to FIG. 2B, the islands 260a, 260b and 260c are then heated and softened to form microlenses 260d, 260e and 260f, respectively, via the surface tension effect, wherein the thicker an island is, the larger the curvature of the corresponding microlens is. Since the island 260a is thicker than the island 260b and 260b thicker than 260c, respective curvatures C1, C2 and C3 of the microlenses 260d, 260e and 260f satisfy the inequality of “C1>C2>C3”. Accordingly, respective focal lengths L1, L2 and L3 of the microlens 260f, 260e and 260d satisfy the inequality of “L1>L2>L3”.

Since the depths D1, D2 and D3 of the maximal absorption regions 142, 132 and 122 respectively for red light, green light and blue light satisfy the inequality of “D1>D2>D3”, by carefully adjusting the transparencies of the mask patterns 270a, 270b and 270c, the microlenses 260d, 260e and 260f can be formed such that the blue light 224, the green light 234 and the red light 244 are respectively focused to the maximal absorption regions 122, 132 and 142.

According to the above preferred embodiment, the microlenses of three different curvatures are form with only one lithography process by varying pattern transparencies on a single photomask, so that much process time is saved as compared with the prior art that forms microlenses of different curvatures with three lithography processes. Meanwhile, since each of the blue, green and red lights are focused to the corresponding maximal absorption region, the sensitivities to the colors are optimized respectively. Therefore, the overall sensitivity of the solid-state image sensor can be improved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for forming microlenses of different curvatures, comprising:
forming a transparent photosensitive layer on a substrate that has a planar upper surface;
using a photomask to pattern the photosensitive layer, the photomask having at least two patterns of different transparencies thereon, such that at least two islands of different thicknesses are defined from the photosensitive layer, wherein the higher the transparency of a pattern is, the thinner the corresponding island is; and
heating and softening the at least two islands to form at least two microlenses of different curvatures, wherein the thicker an island is, the larger the curvature of the corresponding microlens is.

2. The method of claim 1, wherein the planar upper surface of the substrate comprises an upper surface of a planarization layer.

3. The method of claim 1, which is applied to a fabricating process of a solid-state image sensor that includes a first, a second and a third sensors respectively for sensing a first, a second and a third color lights and respectively having a first, a second and a third maximal absorption regions different in depth in the substrate, wherein
the first to third color lights can be combined to obtain full colors; and
the photomask has three patterns of three different transparencies thereon, such that three islands of three different thicknesses are defined for forming three microlenses of three different curvatures,
wherein the three islands are respectively formed over the first, the second and the third maximal absorption regions in a manner that the deeper a maximal absorption region is, the thinner the corresponding island is, such that the three microlenses are formed with three different curvatures capable of focusing the first to third color lights respectively to the first, the second and the third maximal absorption regions.

4. The method of claim 3, which is performed after color filters of the first to third color lights are formed, wherein each microlens is formed over one color filter.

5. The method of claim 4, which is not performed until a planarization layer is formed covering the color filters of the first to third color lights.

6. The method of claim 3, wherein the first to third color lights are red light, green light and blue light, respectively.

7. The method of claim 6, wherein
the solid-state image sensor comprises a CMOS image sensor;
the first to third maximal absorption regions are respectively at depths D1, D2 and D3 in the substrate satisfying an inequality of “D1>D2>D3”;
the three microlenses includes a first, a second and a third microlenses respectively having curvatures C1, C2 and C3 satisfying an inequality of “C1>C2>C3”; and
the first, the second and the third microlenses are respectively formed over the third, the second and the first maximal absorption regions of the blue light, the green light and the red light, respectively.

8. A method for fabricating a solid-state image sensor, comprising:
providing a substrate that includes first to third color filters of first to third color lights, wherein first to third maximal absorption regions of the first to third color lights are different in depth in the substrate, and the first to third color lights can be combined to obtain full colors;
forming a transparent photosensitive layer over the substrate;
using a photomask to pattern the photosensitive layer, the photomask having three patterns of three different transparencies thereon, such that three islands of three different thicknesses are defined from the photosensitive layer, wherein the higher the transparency of a pattern is, the thinner the corresponding island is; and
heating and softening the three islands to form three microlenses of three different curvatures,
wherein the three islands are respectively formed over the first, the second and the third color filters in a manner that the deeper a maximal absorption region is, the thinner the corresponding island is, such that the three microlenses are formed with three different curvatures capable of focusing the first to third color lights respectively to the first, the second and the third maximal absorption regions.

9. The method of claim 8, wherein the first to third color light are red light, green light and blue light, respectively.

10. The method of claim 9, wherein
the solid-state image sensor comprises a CMOS image sensor;
the first to third maximal absorption regions are respectively at depths D1, D2 and D3 in the substrate satisfying an inequality of “D1>D2>D3”;
the three microlenses includes a first, a second and a third microlenses respectively having curvatures C1, C2 and C3 satisfying an inequality of “C1>C2>C3”; and
the first, the second and the third microlenses are respectively formed over the third, the second and the first maximal absorption regions of the blue light, the green light and the red light, respectively.

11. The method of claim 8, further comprising forming a planarization layer covering the color filters before the transparent photosensitive layer is formed.

12. The method of claim 11, wherein the planarization layer comprises a spin-on polymer (SOP).

13. The method of claim 8, wherein the first to third color filters have substantially the same top height, and the photosensitive layer is directly formed on the color filters.

14. The method of claim 8, wherein the substrate provided further comprises a passivation layer under the color filters for protecting a circuit of the solid-state image sensor.

15. The method of claim 14, wherein the passivation layer comprises SiO2.
